(19) United States
(12) Patent Application Publication
(10) Pub. No.: US 2026/0068394 A1
(43) Pub. Date: Mar. 5, 2026

(54) DISPLAY DEVICE AND HEAD MOUNTED DISPLAY APPARATUS

(71) Applicant: LG Display Co., Ltd., Seoul (KR)

(72) Inventors: Beom-Gon JO, Paju-si (KR); Hoon-Sok SON, Paju-si (KR); Hak-Min LEE, Paju-si (KR); Min-Ki KIM, Paju-si (KR)

(73) Assignee: LG Display Co., Ltd., Seoul (KR)

(21) Appl. No.: 19/260,220

(22) Filed: Jul. 3, 2025

(30) Foreign Application Priority Data
Aug. 30, 2024 (KR) 10-2024-0117298

(51) Int. Cl. H10H 29/80; G02B 27/01; H01L 25/16; H10H 29/37; H10K 59/121; H10K 59/122; H10K 59/60; H10K 59/80

(52) U.S. Cl. CPC H10H 29/8325; G02B 27/0176; H10H 29/37; H10H 29/8321; H10K 59/1213; H10K 59/122; H10K 59/60; H10K 59/80515; H10K 59/80518; H10K 59/80521; G02B 2027/0178

(57) ABSTRACT

A display device includes: an infrared light emitting diode in a first subpixel and in which a second anode electrode, an infrared emitting layer, and a second cathode electrode are stacked; a dielectric layer on the infrared light emitting diode; and a light emitting diode in the first subpixel and in which a first anode electrode, a light emitting layer, and a first cathode electrode are stacked on the dielectric layer, wherein a structure configured with the second cathode electrode, the dielectric layer, and the first anode electrode reflects visible light and transmits infrared ray.

### CROSS REFERENCE TO RELATED APPLICATION

The present application claims the priority benefit of Korean Patent Application No. 10-2024-0117298, filed in the Republic of Korea on Aug. 30, 2024, which is hereby incorporated by reference in its entirety for all purposes as if fully set forth herein.

### BACKGROUND

### Field of the Disclosure

The present disclosure relates to a display device and a head mounted display apparatus.

### Discussion of the Related Art

Recently, virtual reality (VR), mixed reality (MR), extended reality (XR) and the like are being implemented through a head mounted display (HMD) apparatus.

The head mounted display apparatus that realizes user experiences is additionally equipped with infrared light emitting elements and infrared sensing elements to track the user's gaze.

As the infrared light emitting elements and sensing elements are additionally equipped, weight and volume of the head mounted display apparatus increase and wearing comfort deteriorates.

### SUMMARY

An advantage of the present disclosure is to provide a display device and a head mounted display apparatus that can alleviate problems caused by additional installation of infrared light emitting elements and sensing elements, thereby realizing miniaturization and weight reduction of the head mounted display apparatus and improving user's wearing comfort.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate including a first subpixel; an infrared light emitting diode which is in the first subpixel on the substrate and in which a second anode electrode, an infrared emitting layer, and a second cathode electrode are stacked; a dielectric layer on the infrared light emitting diode; and a light emitting diode which is in the first subpixel and in which a first anode electrode, a light emitting layer, and a first cathode electrode are stacked on the dielectric layer, wherein a structure configured with the second cathode electrode, the dielectric layer, and the first anode electrode reflects visible light and transmits infrared ray.

In another aspect, a display device includes: a substrate including a plurality of subpixels; a light emitting diode in one of the plurality of subpixels and emitting visible light; an infrared light emitting diode or an infrared photodiode positioned below the light emitting diode in the one of the plurality of subpixels, the infrared light emitting diode emitting infrared ray, the infrared photodiode receiving the infrared ray; and a dielectric layer interposed between a first anode electrode of the light emitting diode and a second cathode electrode of the infrared light emitting diode or the infrared photodiode, wherein each of the first anode electrode and the second cathode electrode is formed of a metal and has a thickness in a range from 150 Å to 250 Å, and wherein the dielectric layer has a thickness in a range from 9800 Å to 10000 Å.

In another aspect, a head mounted display apparatus includes: the above display device; and an apparatus frame on which the display device is mounted.

It is to be understood that both the foregoing general description and the following detailed description are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the disclosure and together with the description serve to explain various principles of the disclosure. In the drawings:

FIG. 1 is a view schematically illustrating a structure of a head mounted display apparatus including a display panel according to an example embodiment of the present disclosure;

FIG. 2 is a view schematically illustrating a configuration of a head mounted display apparatus according to an example embodiment of the present disclosure;

FIG. 3 is a view schematically illustrating a circuit structure of subpixels equipped with an infrared light emitting diode and an infrared photodiode according to an example embodiment of the present disclosure;

FIG. 4 is a plan view schematically illustrating a display panel according to an example embodiment of the present disclosure;

FIGS. 5 and 6 are cross-sectional views taken along lines V-V′ and VI-VI′ in FIG. 4, respectively;

FIGS. 7A and 7B are views illustrating experimental results of transmittance and reflectance with respect to wavelength of a selective transmission structure configured with metal layer/dielectric layer/metal layer according to an example embodiment of the present disclosure; and

FIGS. 8A and 8B are views illustrating a user's gaze tracking through a display panel having a user gaze tracking module built in according to an example embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms. The present disclosure is provided to fully inform the scope of the disclosure to the skilled in the art of the present disclosure, and the protected scope of the present disclosure may be defined by the scope of the claims and their equivalents.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, where a detailed description of the related known technology may unnecessarily obscure the subject matter of the present disclosure, the detailed description thereof can be omitted. Where ‘comprising’, ‘including’, ‘having’, ‘consisting’, and the like are used in this disclosure, other parts can be added unless a more limiting term like ‘only’ is used. Where a component is expressed in the singular, cases including the plural are included unless specific statement is described.

In interpreting the components, even if there is no separate explicit description, they should be interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless a more limiting term like ‘right’ or ‘directly’ is used.

In the case of a description of a temporal relationship, for example, when a temporal precedence is described as ‘after’, ‘following’, ‘before’, and the like, cases that are not continuous can be included unless a more limiting term like ‘directly’ or ‘immediately’ is used.

In describing components of the present disclosure, terms such as first, second and the like can be used. These terms are only for referring to the components separately from other components, and an essence, order, order, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, example embodiments of the present disclosure are described in detail with reference to the drawings. In the following example embodiments, the same and like reference numerals are assigned to the same and like components, and detailed descriptions thereof may be omitted.

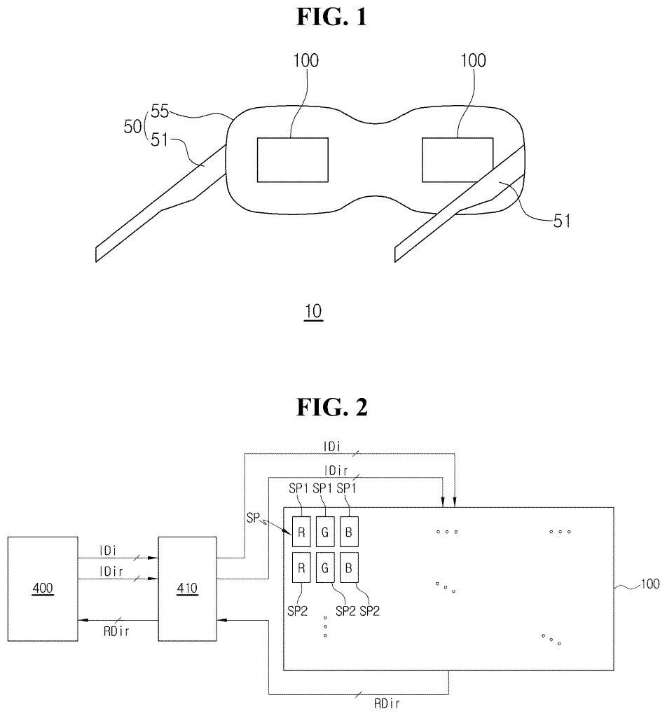

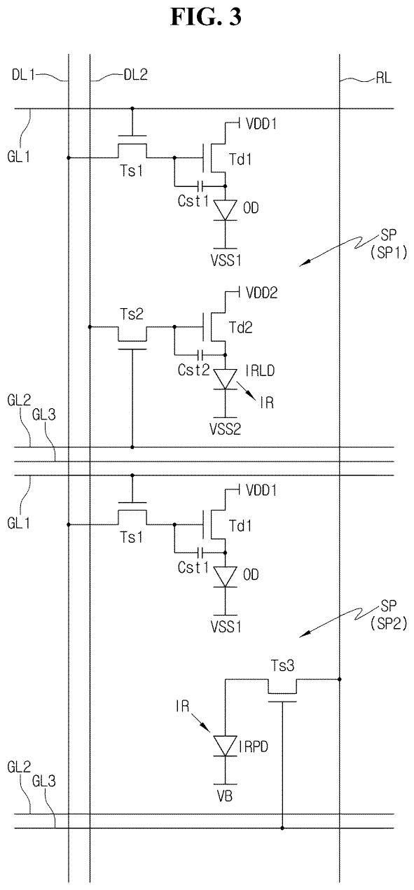

FIG. 1 is a view schematically illustrating a structure of a head mounted display apparatus including a display panel according to an example embodiment of the present disclosure. FIG. 2 is a view schematically illustrating a configuration of a head mounted display apparatus according to an example embodiment of the present disclosure.

As shown in FIGS. 1 and 2, the head mounted display apparatus 10 of the present embodiment can be an electronic apparatus that is worn on a user's head and provides a user with various experiences such as VR, MR, XR and the like.

The head mounted display apparatus 10 can include, for example, an apparatus frame (or housing) 50, a display panel (or display device) 100 mounted (or installed) on the apparatus frame 50 and displaying an image, and a driving circuit portion mounted on the apparatus frame 50 and driving the display device 100.

Here, the driving circuit portion can include, for example, a processor 400 and a panel driving circuit 410.

In the head mounted display apparatus 10 of this example embodiment, for example, infrared elements for tracking the user's gaze using infrared rays, such as infrared light emitting elements and infrared sensing elements (or infrared light receiving elements), can be configured to be built into the display panel 100.

As such, since the infrared light emitting elements and the infrared sensing elements for tracking the user's gaze are formed within the display panel 100, the infrared light-emitting elements and the infrared sensing elements do not need to be separately additionally mounted on the apparatus frame 50 of the head mounted display device 10.

Therefore, there is an effect of alleviating problems caused by the additional mounting of the infrared light emitting elements and sensing elements, realizing miniaturization and weight reduction of the head mounted display apparatus 10, and improving the user's wearing comfort.

The structure in which the infrared light emitting elements and the infrared sensing elements are built into the display panel 100 is described in more detail below.

The apparatus frame 50 is an apparatus body that defines an outer shape of the head mounted display apparatus 10, and can include a first frame 51 and a second frame 55.

The first frame 51 can be, for example, a portion which directly contacts the user's head to allow the head mounted display apparatus 10 to be mounted on the user. The driving circuit portion can be, for example, built into the first frame 51. As another example, the driving circuit portion can be built into the second frame 55 or can be built into both the first and second frames 51 and 55.

The second frame 55 can be a portion which is connected to a front end of the first frame 51 and which the display panel 100, which is positioned in front corresponding to each of the user's eyes, for example, the left and right eyes, is mounted into. The second frame 55 can be formed integrally with the first frame 51 or can be formed separately from the first frame 51 and combined with the first frame 51.

The display panel 100 can generate and output an image provided to the user. The display panel 100 can be configured as a light emitting display panel (e.g., an organic light emitting display panel) that displays an image through light emitting diodes which are light emitting elements that emits visible light.

In the display panel 100, a plurality of subpixels SP can be arranged in a matrix form along a row direction (or a first direction) and a column direction (or a second direction). The plurality of subpixels SP can include, for example, red (R), green (G), and blue (B) subpixels SP that respectively display different primary colors, namely, red (R), green (G), and blue (B). Adjacent red, green, and blue sub-pixels SP can form one pixel which is a unit expressing full color.

The display panel 100 can, for example, receive image data (or image data voltages) IDi provided from the panel driving circuit 410, and in response thereto, drive the light emitting diode for each subpixel SP to generate and output an image.

The image generated and output from the display panel 100 can be provided to the user's eyes, so that the user can recognize the image.

Meanwhile, as mentioned above, the display panel 100 can generate and output infrared rays used to track the user's gaze, i.e., the position of the user's eyes, and the infrared rays can be incident on the user's eyes and then reflected and then be incident on the display panel 100. In addition, the display panel 100 can detect the infrared rays incident on the display panel 100, and can generate and output corresponding sensing data RDir.

In implementing such infrared light emission and sensing in the display panel 100, for example, an infrared light emitting diode as an infrared light emitting element can be provided in at least some of the plurality of subpixels SP. In addition, an infrared photodiode as an infrared sensing element can be provided in at least some of the plurality of subpixels SP.

In terms of uniform infrared light emission, the infrared light emitting diodes can be uniformly arranged in the display panel 100, but not limited thereto. And, in terms of uniform infrared sensing, the infrared photodiodes can be uniformly arranged in the display panel 100, but not limited thereto.

Meanwhile, the subpixel SP in which the infrared light emitting diode is arranged and the subpixel SP in which the infrared photodiode is arranged can be different from each other. In other words, the subpixel SP in which the infrared light emitting diode is arranged may not have the infrared photodiode, and the subpixel SP in which the infrared photodiode is arranged may not have the infrared light emitting diode. As such, a region where the infrared light emitting diode is arranged and a region where the infrared photodiode is arranged can be different from each other. Embodiments are not limited thereto. As an example, the subpixel SP in which the infrared light emitting diode is arranged and the subpixel SP in which the infrared photodiode is arranged can be the same as each other. As an example, a region where the infrared light emitting diode is arranged and a region where the infrared photodiode is arranged can be partially or fully overlap each other.

In some subpixels SP within the display panel 100, the infrared light emitting diode and the infrared photodiode may not be arranged. In other words, in some subpixels SP, the light emitting diodes for displaying an image can be formed, and neither the infrared light emitting diode nor the infrared photodiode may be formed. Embodiments are not limited thereto. As an example, each of the subpixels SP within the display panel 100 can include at least one of or both of the infrared light emitting diode and the infrared photodiode, without being limited thereto.

As above, the infrared light emitting diode and the infrared photodiode can be arranged in various forms in the display panel 100.

In this example embodiment, for the convenience of explanations, an example is given where the infrared light emitting diode and the infrared photodiode are arranged in different subpixels SP, and the infrared light emitting diode and the infrared photodiode are alternately arranged in the subpixels SP along each column line. In other words, an example is given where the subpixels SP including the infrared light emitting diodes are arranged along a row line, and the subpixels SP including the infrared photodiodes are arranged along an adjacent row line.

Alternatively, the infrared light emitting diode and the infrared photodiode can be arranged adjacent to each other along a column line and a row line, or can be alternately arranged with at least one subpixel SP interposed therebetween.

Here, for convenience of explanations, the subpixel SP including the infrared light emitting diode can be referred to as a first subpixel SP1, and the subpixel SP including the infrared photodiode can be referred to as a second subpixel SP2. In other words, the subpixel SP in which the infrared light emitting diode is arranged together with the light emitting diode that displays an image can be referred to as the first subpixel SP1, and the subpixel SP in which the infrared photodiode is arranged together with the light emitting diode that displays an image can be referred to as the second subpixel SP2.

In this case, the display panel 100 can receive, for example, infrared emission data IDir provided from the panel driving circuit 410, and in response thereto, drive the infrared light emitting diode in the corresponding first sub pixel SP1 to generate the infrared ray and output the infrared ray to the user's eyes.

As such, the infrared ray generated and output from the infrared light emitting diode of the first subpixel SP1 of the display panel 100 can be reflected from the user's eyes and input again to the display panel 100.

The infrared ray input to the display panel 100 can be sensed by, for example, a the infrared photodiode of the second sub-pixel SP2 through a photoelectric effect, and the sensing data (or infrared sensing data) RDir can be generated and output.

As such, the sensing data RDir output from the second subpixel SP2 of the display panel 100 can be provided to the panel driving circuit 410.

The panel driving circuit 410 can process the sensing data RDir and provide it to the processor 400.

As mentioned above, the processor 400 can output the image data IDi for image display and the infrared emission data IDir for infrared emission to the panel driving circuit 410.

In addition, the processor 400 can receive the sensing data RDir, which is infrared sensing information, from the panel driving circuit 410. The processor 400 can analyze the sensing data RDir to obtain gaze information including the user's eye position, eye blinking, etc. The gaze information can be used as user input information, and according to such the input information, corresponding image data IDi can be provided to the panel driving circuit 410.

Hereinafter, a configuration of the subpixel SP equipped with the infrared light emitting diode and the infrared photodiode of this example embodiment is explained in more detail.

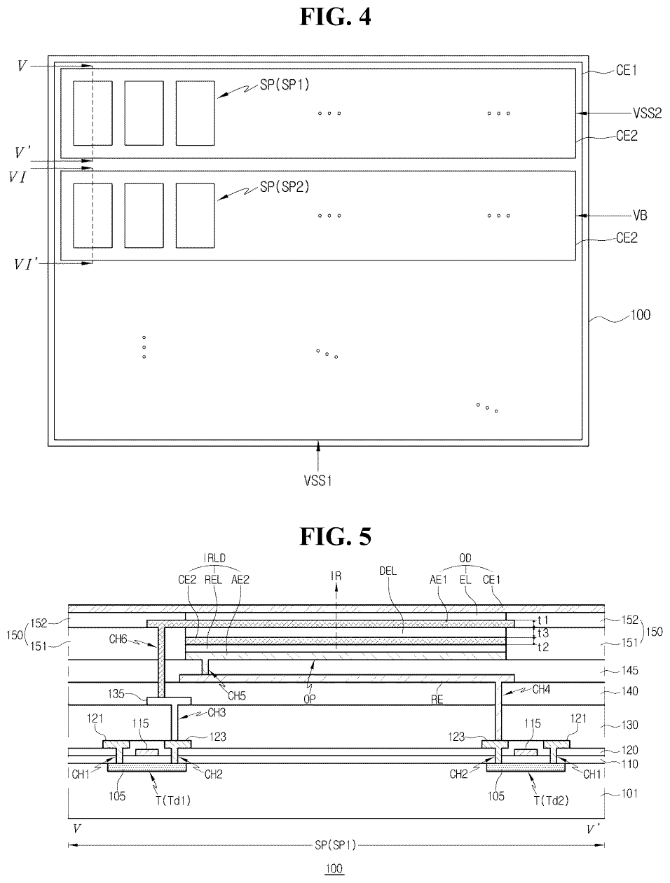

FIG. 3 is a view schematically illustrating a circuit structure of subpixels equipped with an infrared light emitting diode and an infrared photodiode according to an example embodiment of the present disclosure.

In FIG. 3, as mentioned above, the case where the first subpixel SP1 and the second subpixel SP2 are alternately arranged along a column line is taken as an example.

As shown in FIG. 3 together with FIGS. 1 and 2, the first subpixel SP1 can include a light emitting diode (or first light emitting diode) OD that displays an image and an infrared light emitting diode (or second light emitting diode) IRLD that emits infrared rays IR.

In addition, the second subpixel SP2 can include a light emitting diode (or first light emitting diode) OD that displays an image and an infrared photodiode IRPD that senses infrared rays IR.

The first subpixel SP1 can include a pixel driving circuit (or a first pixel driving circuit) that drives the light emitting diode OD and the infrared light emitting diode IRLD.

For example, the first subpixel SP1 can include a switching transistor Ts1, a driving transistor Td1, and a storage capacitor Cst1 which drive the light emitting diode OD. In addition, the first subpixel SP1 can include a switching transistor Ts2, a driving transistor Td2, and a storage capacitor Cst2 which drive the infrared light emitting diode IRLD. Embodiments are not limited thereto. As an example, one or more of the above-mentioned components can be omitted depending on the design, or one or more transistors or one or more capacitors can be further included in the first subpixel SP1. As an example, the pixel driving circuit of the first subpixel SP1 can be varied in various ways, without being limited to that of FIG. 3.

Here, for the convenience of explanations, the switching transistor Ts1, the driving transistor Td1, and the storage capacitor Cst1 that drive the light emitting diode OD can be referred to as a first switching transistor Ts1, a first driving transistor Td1, and a first storage capacitor Cst1, respectively. In addition, the switching transistor Ts2, the driving transistor Td2, and the storage capacitor Cst2 that drive the infrared light emitting diode IRLD can be referred to as a second switching transistor Ts2, a second driving transistor Td2, and a second storage capacitor Cst2, respectively.

Meanwhile, the structure of the pixel driving circuit of the first subpixel SP1 as described above is an example, and other circuit structure can be used.

The first switching transistor Ts1 can be connected to corresponding first gate line GL1 and first data line DL1. Here, the corresponding image data IDi can be transmitted through the first data line DL1. For example, the first driving transistor Td1 can have a gate electrode connected to a drain electrode of the first switching transistor Ts1, a source electrode applied with a first high potential voltage VDD1, and a drain electrode connected to an anode electrode (or a first anode electrode) of the light emitting diode OD. In addition, a cathode electrode (or a first cathode electrode) of the light emitting diode OD can be applied with a first low potential voltage VSS1. In addition, the first storage capacitor Cst1 can be connected between the gate electrode and the drain electrode of the first driving transistor Td1.

In this case, when the first switching transistor Ts1 is turned on and the image data IDi is input to the first subpixel SP1, the first driving transistor Td1 can be turned on and a driving current can flow to the light emitting diode OD, so that a corresponding visible light can be generated and output from the light emitting diode OD.

In addition, the second switching transistor Ts2 can be connected to corresponding second gate line GL2 and second data line DL2. Here, the corresponding infrared emission data IDir can be transmitted through the second data line DL2. For example, the second driving transistor Td2 can have a gate electrode connected to a drain electrode of the second switching transistor Ts2, a source electrode applied with a second high potential voltage VDD2, and a drain electrode connected to an anode electrode (or a second anode electrode) of the infrared light emitting diode IRLD. In addition, a cathode electrode (or a second cathode electrode) of the infrared light emitting diode IRLD can be applied with a second low potential voltage VSS2. In addition, the second storage capacitor Cst2 can be connected between the gate electrode and the drain electrode of the second driving transistor Td2.

In this case, when the second switching transistor Ts2 is turned on and the infrared emission data IDir is input to the first subpixel SP1, the second driving transistor Td2 can be turned on and a driving current can flow to the infrared light emitting diode IRLD, so that a corresponding infrared ray IR can be generated and output from the infrared light emitting diode IRLD.

Meanwhile, the first high potential voltage VDD1 and the second high potential voltage VDD2 can be the same or different from each other, and the first low potential voltage VSS1 and the second low potential voltage VSS2 can be the same or different from each other.

In addition, in the first subpixel SP1, an emission timing of the light emitting diode OD and an emission timing of the infrared light emitting diode IRLD can be substantially the same or different.

Meanwhile, the second subpixel SP2 can include a pixel driving circuit (or a second pixel driving circuit) that drives the light emitting diode OD and the infrared photodiode IRPD.

For example, similarly to the first subpixel SP1, the second subpixel SP2 can include a first switching transistor Ts1, a first driving transistor Td1, and a first storage capacitor Cst1 which drive the light emitting diode OD. In addition, the second subpixel SP2 can include a third switching transistor Ts3 which is a switching transistor Ts3 for driving the infrared photodiode IRPD.

Meanwhile, the structure of the pixel driving circuit of the second subpixel SP2 as described above is an example, other circuit structure can be used.

The first switching transistor Ts1 can be connected to corresponding first gate line GL1 and first data line DL1. Here, the corresponding image data IDi can be transmitted through the first data line DL1. For example, the first driving transistor Td1 can have a gate electrode connected to a drain electrode of the first switching transistor Ts1, a source electrode applied with a first high potential voltage VDD1, and a drain electrode connected to an anode electrode (or a first anode electrode) of the light emitting diode OD. In addition, a cathode electrode (or first cathode electrode) of the light emitting diode OD can be applied with a first low potential voltage VSS1. In addition, the first storage capacitor Cst1 can be connected between the gate electrode and the drain electrode of the first driving transistor Td1.

In this case, similarly to the first subpixel SP1, when the first switching transistor Ts1 is turned on and the image data IDi is input to the second subpixel SP2, the first driving transistor Td1 can be turned on and a driving current can flow to the light emitting diode OD, so that a corresponding visible light can be generated and output from the light emitting diode OD.

In addition, the third switching transistor Ts3 can be connected to corresponding third gate line GL3 and readout line (or readout data line) RL. In addition, the infrared photodiode IRPD can have an anode electrode (or second anode electrode) connected to the drain electrode of the third switching transistor Ts3, and a cathode electrode (or second cathode electrode) applied with a bias voltage VB.

In this case, the infrared ray IR emitted from the infrared light emitting diode IRLD of the first subpixel SP1 and reflected from the user's eyes can be incident on the infrared photodiode IRPD of the second subpixel SP2, and the sensing data RDir, which is an electrical signal corresponding to the infrared ray incident on the second subpixel SP2, can be generated by a photoelectric effect of the infrared photodiode IRPD. When the third switching transistor Ts3 is turned on, the sensing data RDir can be transmitted through the readout line RL.

Meanwhile, an emission timing of the infrared light emitting diode IRLD and a sensing timing of the infrared photodiode IRPD can be substantially the same or different.

Meanwhile, regarding the arrangement of the first and second data lines DL1 and DL2 and the readout line RL, for example, in the display panel 100, the first and second data lines DL1 and DL2 and the readout line RL can be formed to extend along the column direction. In this case, the first data line DL1 can be connected to each subpixel SP of the corresponding column line, the second data line DL2 can be connected to the first subpixel SP1 of the corresponding column line, and the readout line RL can be connected to the second subpixel SP2 of the corresponding column line.

Regarding the arrangement of the first to third gate lines GL1 to GL3, for example, in the display panel 100, the first to third gate lines GL1 to GL3 can be formed to extend along the row direction. In this example embodiment, for the convenience of explanations, an example is given where the first to third gate lines GL1 to GL3 are arranged in each row line. As an example, the first to third gate lines GL1 to GL3 can be arranged between the first subpixel SP1 and the second subpixel SP2, without being limited thereto.

In this case, the first gate line GL1 can be connected to each subpixel SP of the corresponding row line, the second gate line GL2 can be connected to the first subpixel SP1 of the corresponding row line, and the third gate line GL3 can be connected to the second subpixel SP2 of the corresponding row line.

As described above, in this example embodiment, the infrared light emitting diode IRLD can be located in the first subpixel SP1, and the infrared photodiode IRPD can be located in the second subpixel SP2.

The infrared light emitting diodes IRLD and the infrared photodiodes IRPD can each be configured to be formed below the light emitting diode OD in its subpixel SP, which is described in more detail below.

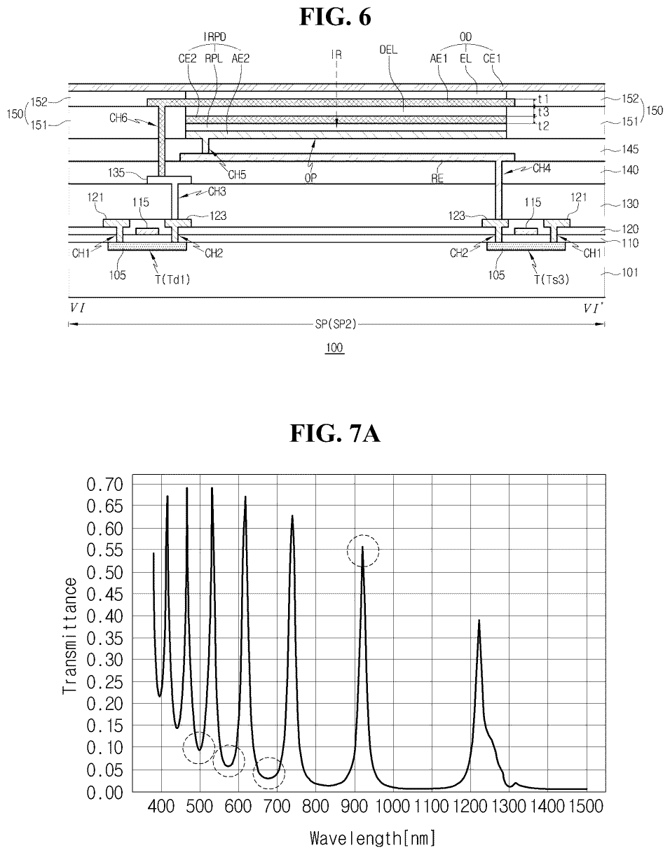

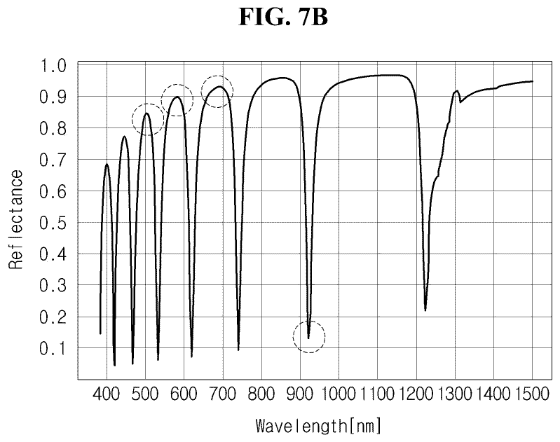

FIG. 4 is a plan view schematically illustrating a display panel according to an example embodiment of the present disclosure. FIGS. 5 and 6 are cross-sectional views, taken along lines V-V′ and VI-VI′ in FIG. 4, respectively, schematically illustrating cross-sectional structures of first and second subpixels.

In FIGS. 4 to 6, for the convenience of explanations, a case is taken where each of the first and second subpixels SP1 and SP2 are arranged in each row line, for example, the first subpixel SP1 is arranged in an odd (or even) row line and the second subpixel SP2 is arranged in an even (or odd) row line.

As shown in FIGS. 4 to 6 together with FIGS. 1 to 3, on a substrate 101 of the display panel 100 of this example embodiment, the infrared light emitting diode IRLD and the light emitting diode OD sequentially stacked in an upward direction can be formed in the first sub-pixel SP1, and the infrared photodiode IRPD and the light emitting diode OD sequentially stacked in an upward direction can be formed in the second subpixel SP2.

In other words, each of the first and second subpixels SP1 and SP2 can include the light emitting diode OD positioned upper that emits visible light of a corresponding color (e.g., red, green, or blue), the infrared light emitting diode IRLD that emits infrared ray IR can be positioned below the light emitting diode OD in the first subpixel SP1, and the infrared photodiode IRPD that senses the infrared ray IR can be positioned below the light emitting diode OD in the second subpixel SP2. As an example, the infrared light emitting diode IRLD that emits infrared ray IR can be positioned to partially or fully overlap the light emitting diode OD in the first subpixel SP1, or can be positioned to be separated from the light emitting diode OD in the first subpixel SP1 horizontally, and the infrared photodiode IRPD that senses the infrared ray IR can be positioned to partially or fully overlap the light emitting diode OD in the second subpixel SP2, or can be positioned to be separated from light emitting diode OD in the second subpixel SP2 horizontally. Embodiments are not limited thereto. As an example, the infrared light emitting diode IRLD can be positioned above the light emitting diode OD in the first subpixel SP1 or on the substantially the same layer as the light emitting diode OD in the first subpixel SP1, or the infrared photodiode IRPD that senses the infrared ray IR can be positioned above the light emitting diode OD in the second subpixel SP2 or on the substantially the same layer as the light emitting diode OD in the second subpixel SP2.

Meanwhile, as mentioned above, among the subpixels SP in the display panel 100, unlike the first and second subpixels SP1 and SP2, there can be subpixels SP that are not provided with the infrared light emitting diode IRLD and the infrared photodiode IRPD, and in this case, the light emitting diodes OD of such the subpixels SP can be formed to contact an upper surface of a planarization layer 145 therebelow. In this example embodiment, the substrate 101 of the display panel 100 can use, for example, a silicon wafer, or a glass substrate or plastic substrate having insulating properties. In this example embodiment, for the convenience of explanations, a case where the substrate 101 is formed of a silicon wafer is taken as an example.

When the substrate 101 is formed of a silicon wafer, a semiconductor layer 105 forming each transistor (or thin film transistor) T in each subpixel SP can be formed in the substrate 101.

For example, the semiconductor layer 105 of each of the first switching transistor Ts1, the first driving transistor Td1, the second switching transistor Ts2, and the second driving transistor Td2 of the first subpixel SP1 can be formed in the substrate 101. In addition, the semiconductor layer 105 of each of the first switching transistor Ts1, the first driving transistor Td1, and the third switching transistor Ts3 of the second subpixel SP2 can be formed in the substrate 101. Embodiments are not limited thereto. As an example, at least one of the semiconductor layers 105 of the first switching transistor Ts1, the first driving transistor Td1, the second switching transistor Ts2, and the second driving transistor Td2 of the first subpixel SP1 and the semiconductor layers 105 of the first switching transistor Ts1, the first driving transistor Td1, and the third switching transistor Ts3 of the second subpixel SP2 can be formed on a layer other than the substrate 101 (e.g., above the substrate 101), without being limited thereto.

Meanwhile, in FIGS. 5 and 6, for the convenience of explanations, the first driving transistor Td1, the second driving transistor Td2, and the third switching transistor Ts3 are shown.

The semiconductor layer 105 can include a channel region in the middle and a source region and a drain region on both sides of the channel region. The semiconductor layer 105 can be formed of polycrystalline silicon.

As another example, when the substrate 101 is formed of a glass substrate or plastic substrate, the semiconductor layer 105 can be formed on the substrate 101, and in this case, the semiconductor layer 105 can be formed of polycrystalline silicon, amorphous silicon, or an oxide semiconductor.

A gate insulating layer 110 can be formed on the substrate 101 having the semiconductor layer 105. The gate insulating layer 110 can be formed of, for example, an inorganic insulating material such as silicon oxide (SiO2) or silicon nitride (SiNx).

A gate electrode 115 forming each transistor T can be formed on the gate insulating layer 110.

An interlayered insulating layer 120 can be formed on the gate electrode 115. The interlayered insulating layer 120 can be formed of, for example, an inorganic insulating material, such as silicon oxide (SiO2) or silicon nitride (SiNx).

A first contact hole CH1 and a second contact hole CH2 respectively exposing the source region and drain region of the semiconductor layer 105 of each transistor T can be formed in the interlayered insulating layer 120 and the gate insulating layer 110.

On the interlayered insulating layer 120, a source electrode 121 and a drain electrode 123 forming each transistor T can be formed. Here, the source electrode 121 can contact the source region of the semiconductor layer 105 through the corresponding first contact hole CH1, and the drain electrode 123 can contact the drain region of the semiconductor layer 105 through the corresponding second contact hole CH2.

A first passivation layer 130 can be formed on the source electrode 121 and the drain electrode 123. The first passivation layer 130 can be formed of, for example, an inorganic insulating material such as silicon oxide (SiO2) or silicon nitride (SiNx), or an organic insulating material such as photo acrylic or benzocyclobutene. Meanwhile, the first passivation layer 130 can be formed of at least one insulating layer. In the first passivation layer 130, for example, a third contact hole CH3 exposing the drain electrode 123 of the first driving transistor Td1 can be formed.

A connection electrode 135 can be formed on the first passivation layer 130. The connection electrode 135 can be connected to the drain electrode 123 of the first driving transistor Td1 through the third contact hole CH3. Embodiments are not limited thereto. As an example, the connection electrode 135 can be omitted depending on the design.

A second passivation layer 140 can be formed on the connection electrode 135. The second passivation layer 140 can be formed of, for example, an inorganic insulating material such as silicon oxide (SiO2) or silicon nitride (SiNx), or an organic insulating material such as photo acrylic or benzocyclobutene. Meanwhile, the second passivation layer 140 can be formed of at least one insulating layer.

In the first and second passivation layers 130 and 140, for example, a fourth contact hole CH4 exposing each of the drain electrode 123 of the second driving transistor Td2 and the drain electrode 123 of the third switching transistor Ts3 can be formed.

A reflective electrode RE can be formed on the second passivation layer 140. The reflective electrode RE can be connected to a corresponding one of the drain electrode 123 of the second driving transistor Td2 and the drain electrode 123 of the third switching transistor Ts3 through the fourth contact hole CH4. More specifically, in the first subpixel SP1, the reflective electrode RE can be connected to the drain electrode 123 of the second driving transistor Td2 through the fourth contact hole CH4, and in the second subpixel SP2, the reflective electrode RE can be connected to the drain electrode 123 of the third switching transistor Ts3 through the fourth contact hole CH4. As an example, the reflective electrode RE can be omitted depending on the design.

The reflective electrode RE can be arranged to face each of the infrared light emitting diode IRLD and the infrared photodiodes IRPD located thereon.

The reflective electrode RE can reflect the infrared ray IR to improve infrared emission efficiency and infrared reception efficiency (or infrared sensing efficiency).

In this regard, in the first subpixel SP1, among the infrared rays IR generated from the infrared light emitting diode IRLD, the infrared ray IR that propagates downward can be reflected by the reflective electrode RE and propagate upward toward the user, so that the infrared emission efficiency of the first subpixel SP1 can be increased. In addition, in the second subpixel SP2, among the infrared rays IR that is incident thereon, the infrared ray IR that passes through the infrared photodiode IRPD and propagates downward can be reflected by the reflective electrode RE and be incident on the infrared photodiode IRPD, so that the infrared reception efficiency of the second subpixel SP2 can be increased.

A planarization layer 145 can be formed on the reflective electrode RE. The planarization layer 145 can be formed of, for example, an inorganic insulating material such as silicon oxide (SiO2) or silicon nitride (SiNx), or an organic insulating material such as photo acrylic or benzocyclobutene. Meanwhile, the planarization layer 145 can be formed of at least one insulating layer.

For example, a fifth contact hole CH5 exposing the reflective electrode RE can be formed on the planarization layer 145.

On the planarization layer 145, the infrared light emitting diode IRLD can be formed in the first subpixel SP1, and the infrared photodiode IRPD may be formed on the second subpixel SP2.

In this regard, for example, a second anode electrode AE2 can be formed on the planarization layer 145 in each of the first and second subpixels SP1 and SP2. Here, the second anode electrode AE2 can be formed of a conductive material having a transmissive characteristic (or infrared transmissive characteristic), such as TiN, but not limited thereto. In a case where the second anode electrode AE2 is formed of TiN, it can have a thickness of, for example, approximately 10 Å to 1000 Å to implement the transmissive characteristic (or infrared transmissive characteristic).

The second anode electrode AE2 can be connected to the reflective electrode RE through the fifth contact hole CH5. Accordingly, in the first subpixel SP1, the second anode electrode AE2 can be electrically connected to the drain electrode 123 of the second driving transistor Td2 through the reflective electrode RE. In the second subpixel SP2, the second anode electrode AE2 can be electrically connected to the drain electrode 123 of the third switching transistor Ts3 through the reflective electrode RE. Embodiments are not limited thereto. As an example, the reflective electrode RE can be floated or connected to another electrode, without being connected to the second anode electrode AE2. As an example, the second anode electrode AE2 can be electrically connected to the drain electrode 123 of the second driving transistor Td2 without through the reflective electrode RE, and in the second subpixel SP2, the second anode electrode AE2 can be electrically connected to the drain electrode 123 of the third switching transistor Ts3 without through the reflective electrode RE.

In addition, in the first subpixel SP1, an infrared emitting layer REL that emits the infrared rays IR can be formed on the second anode electrode AE2. Meanwhile, in the second subpixel SP2, an infrared receiving layer RPL, which is a photoelectric layer that receives and senses the infrared rays IR, can be formed on the second anode electrode AE2.

Here, the infrared emitting layer REL can be formed using, for example, an organic material and/or an inorganic material. The infrared receiving layer RPL may be formed using, for example, an organic material and/or an inorganic material.

A second cathode electrode CE2 can be formed on each of the infrared emitting layer REL of the first subpixel SP1 and the infrared receiving layer RPL of the second subpixel SP2.

Here, the second cathode electrode CE2 can be formed to have an extended form, for example, in a row-line unit or a column-line unit. In this example embodiment, for the convenience of explanations, a case in which the second cathode electrode CE2 is formed to extend along each row line, as shown in FIG. 4, is taken as an example. In this case, the second cathode electrode CE2 can be connected to, for example, a voltage pad at its end(s) (for example, both ends or one end) to receive a corresponding second low potential voltage (VSS2) or bias voltage VB. In this regard, the second cathode electrode CE2 positioned in the row line on which the first subpixels SP1 are arranged can receive the second low potential voltage VSS2 through the corresponding voltage pad, and the second cathode electrode CE2 positioned in the row line on which the second subpixels SP2 are arranged can receive the bias voltage VB through the corresponding voltage pad. Embodiments are not limited thereto. As an example, the second cathode electrode CE2 can be formed for each subpixel, or can be formed commonly for all of the subpixels, without being limited thereto.

As described above, the infrared light emitting diode IRLD configured with the second anode electrode AE2, the infrared emitting layer REL, and the second cathode electrode CE2 can be formed in the first subpixel SP1, and the infrared photodiode IRPD configured with the second anode electrode AE2, the infrared receiving layer RPL, and the second cathode electrode CE2 can be formed in the second subpixel SP2.

On the infrared light emitting diode IRLD and the infrared photodiode IRPD, a dielectric layer DEL can be formed in each of the first and second subpixels SP1 and SP2. Embodiments are not limited thereto. As an example, the dielectric layer DEL can be formed commonly for all or some of the subpixels, without being limited thereto.

On the dielectric layer DEL, the light emitting diode OD emitting visible light of a color can be formed in each of the first and second subpixels SP1 and SP2.

For example, a first anode electrode AE1 can be formed on the dielectric layer DEL in each of the first and second subpixels SP1 and SP2.

In addition, a light emitting layer (or visible light emitting layer) EL that emits visible light of a color can be formed on the first anode electrode AE1 in each of the first and second subpixels SP1 and SP2. As another example, the light emitting layer EL of the subpixel SP can be configured as a white light emitting layer that emits white light, and in this case, a color filter that expresses a corresponding color can be provided on the light emitting diode OD and/or the light emitting diode OD can be configured to have a micro-cavity structure to emit a corresponding color.

Here, the light emitting layer EL can be formed using, for example, an organic material and/or an inorganic material. In this example embodiment, for the convenience of explanations, an example in which the light emitting layer EL is formed of an organic material is taken. A first cathode electrode CE1 can be formed on the light emitting layer EL of each subpixel SP. The first cathode electrode CE1 can be formed of, for example, a transparent conductive material such as ITO or IZO, but not limited thereto.

Here, the first cathode electrode CE1 can have, for example, a shape integrally formed to substantially correspond to an entire display region of the display panel 100 (or correspond to all subpixels SP), as shown in FIG. 4. In this case, for example, the first cathode electrode CE1 can be connected to a voltage pad, to which a first low potential voltage VSS1 is input, at its edge, and can receive the first low potential voltage VSS1.

As described above, the light emitting diode OD configured with the first anode electrode AE1, the light emitting layer EL, and the first cathode electrode CE1 can be formed in each subpixel SP.

Meanwhile, a bank 150 can be formed along a boundary of each subpixel SP, and an opening OP can be formed inside the bank 150. The opening OP of the bank 165 can define a light emission region (or a visible light emission area) of the subpixel SP. Furthermore, the opening OP of the first subpixel SP1 can define the light emission region and an infrared emission region, and the opening OP of the second subpixel SP2 can define the emission region and an infrared reception region. Embodiments are not limited thereto. As an example, the light emission region and the infrared emission region can be separately formed and can be defined by different openings of the bank 165, or the emission region and the infrared reception region can be separately formed and can be defined by different openings of the bank 165, without being limited thereto.

In this regard, the light emitting diode OD and the infrared light emitting diode IRLD can be configured in the opening OP of the first subpixel SP1, and the light emitting diode OD and the infrared photodiode IRPD can be configured in the opening OP of the second subpixel SP2.

The bank 150 can include, for example, a first bank layer 151 positioned lower and a second bank layer 152 stacked on the first bank layer 151, or can include one single layer or three or more layers, without being limited thereto.

In this case, edges of the first anode electrode AE1 can extend over an upper surface of the first bank layer 151, and the edges of the first anode electrode AE1 can be covered by the second bank layer 152.

In addition, a sixth contact hole CH6 exposing the connection electrode 135 can be formed in the first bank layer 151, the planarization layer 145 and the second passivation layer 140.

Through the sixth contact hole CH6, the first anode electrode AE1 can be connected to the connection electrode 135. Accordingly, in each subpixel SP, the first anode electrode AE1 can be electrically connected to the drain electrode 123 of the first driving transistor Td1 through the connection electrode 135.

Meanwhile, the connection structure of the first anode electrode AE1 and the first driving transistor Td1 as described above is an example, and other connection structure can be implemented.

As described above, in this example embodiment, the infrared light emitting diode IRLD or the infrared photodiode IRPD can be configured to be located below the light emitting diode OD with the dielectric layer DEL interposed therebetween.

The first anode electrode AE1 of the light emitting diode OD, the second cathode electrode CE2 of the infrared light emitting diode IRLD or infrared photodiode IRPD below the first anode electrode AE1, and the dielectric layer DEL therebetween can be configured to implement a characteristic of reflecting visible light and transmitting infrared ray IR i.e., a selective transmission characteristic (or a selective reflection characteristic).

In other words, the second cathode electrode CE2, the dielectric layer DEL, and the first anode electrode AE1 sequentially laminated in the vertical direction can function as a structure that selectively transmits and reflects light depending on wavelengths i.e., a selective transmission structure.

To implement such the selective transmission structure, for example, the first anode electrode AE1 and the second cathode electrode CE2 can be formed of a metal having a high reflective characteristic, such as Ag, Cu, Al, etc., and the dielectric layer DEL formed of a dielectric material, such as Al2Ox, SiO2, SiNx, etc., can be interposed between the first anode electrode AE1 and the second cathode electrode CE2. Here, the first anode electrode AE1 and the second cathode electrode CE2 can be formed of the same metal or different metals. In addition, the dielectric layer DEL can have a refractive index of, for example, approximately 1.5 to 2.5.

As such, the selective transmission structure configured with the second cathode electrode CE2, the dielectric layer DEL, and the first anode electrode AE1 can have a sandwich structure of metal layer/dielectric layer/metal layer.

By controlling the thickness of the sandwich structure of metal layer/dielectric layer/metal layer, transmittance and reflectance of the selective transmission structure can be set according to wavelengths.

In this regard, in this example embodiment, the thicknesses of the second cathode electrode CE2, the dielectric layer DEL, and the first anode electrode AE1 can be adjusted so that the selective transmission structure can reflect the color lights expressed by the subpixels SP, for example, red light, green light, and blue light, and transmit the infrared rays IR.

For example, a first thickness t1 of the first anode electrode AE1 formed of metal and a second thickness t2 of the second cathode electrode CE2 formed of metal can be approximately 150 Å to 250 Å. Here, the first and second thicknesses t1 and t2 can be the same as or different from each other.

In addition, a third thickness t3 of the dielectric layer DEL can be approximately 9800 Å to 10000 Å which is greater than each of the first and second thicknesses t1 and t2.

In this case, the selective transmission structure can reflect the visible lights in the wavelength ranges of red, green, and blue, and transmit the infrared rays IR, more specifically, the infrared rays IR having a wavelength of about 910 nm to 930 nm.

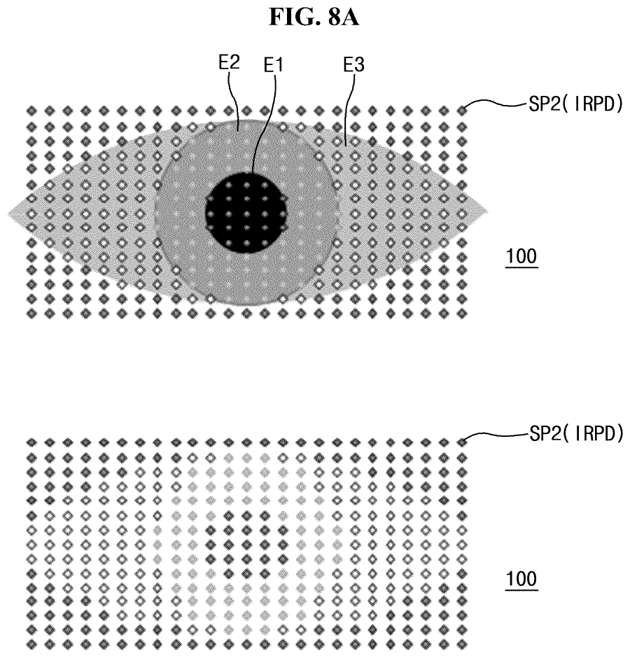

The transmission/reflection characteristics of such the selective transmission structure is explained further with reference to FIGS. 7A and 7B. FIGS. 7A and 7B are views illustrating experimental results of transmittance and reflectance with respect to wavelength of a selective transmission structure configured with metal layer/dielectric layer/metal layer according to an example embodiment of the present disclosure, where FIG. 7A shows transmittance and FIG. 7B shows reflectance.

As shown in FIGS. 7A and 7B, it can be seen that the selective transmission structure configured with metal layer/dielectric layer/metal layer of this example embodiment has very low transmittance and very high reflectance for the wavelength ranges of red, green, and blue, and very high transmittance and very low reflectance for infrared rays IR having a wavelength of about 910 nm to 930 nm.

As described above, in this example embodiment, the selective transmission structure configured with the second cathode electrode CE2, the dielectric layer DEL, and the first anode electrode AE1 can be formed with the sandwich structure of metal layer/dielectric layer/metal layer, so that the selective transmission structure can reflect visible light in the wavelength ranges of red, green, and blue, and transmit the infrared rays IR.

Accordingly, visible light generated from the light emitting diode OD located upper in the subpixel SP can be reflected from the selective transmission structure and transmitted toward the front where the user is positioned, so that the emission efficiency of the visible light can be improved.

In addition, the infrared ray IR generated from the infrared light emitting diode IRLD located below the light emitting diode OD within the first subpixel SP1 can pass through the selective transmission structure and be transmitted toward the front where the user is positioned. In addition, the infrared ray IR reflected from the user's eyes and incident on the second subpixel SP2 can pass through the selective transmission structure and be incident on the infrared photodiode IRPD.

As such, by forming the selective transmission structure in the subpixel SP, the emission efficiency of visible light can be sufficiently secured, while the infrared ray IR for tracking the user's gaze can be generated and irradiated onto the user's eyes, and the reflected infrared IR can be received and sensed.

Accordingly, the infrared light emitting diode IRLD and the infrared photodiode IRPD, which are gaze tracking modules that implement the user's gaze tracking, can be placed below the light emitting diodes OD, so that the user's gaze tracking modules using the infrared ray IR can be effectively embedded within the display panel 100.

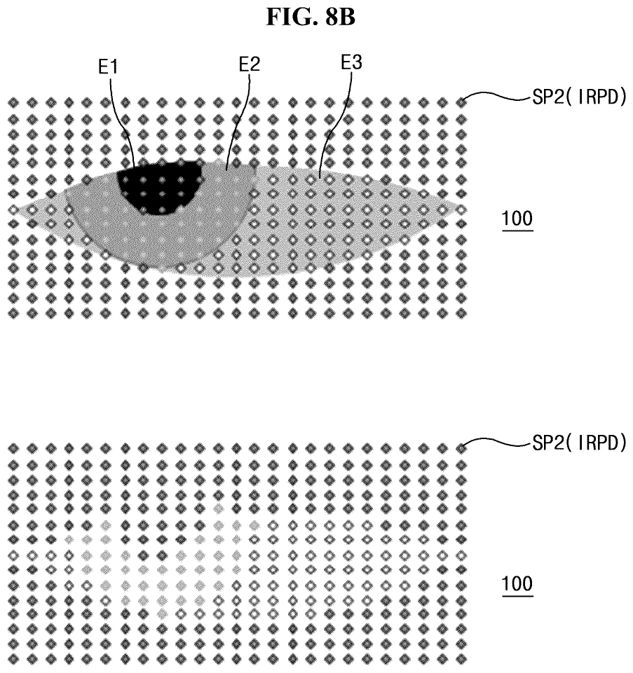

FIGS. 8A and 8B are views illustrating a user's gaze tracking through a display panel having a user gaze tracking module built in according to an example embodiment of the present disclosure. FIG. 8A is a view illustrating a case where user's eyes are directed toward a front, and FIG. 8B is a view illustrating a case where user's eyes are moved to a left.

In FIGS. 8A and 8B, for the convenience of explanations, the infrared photodiodes IRPD formed in the second subpixels SP2 within the display panel 100 are shown. In addition, in each of FIGS. 8A and 8B, an upper portion shows the display panel 100 and the eye by overlapping them, and a lower portion shows the infrared photodiodes IRPD of the display panel 100 excluding the eye.

As shown in FIGS. 8A and 8B, a pupil E1, an iris E2, and a white of an eye E3 that constitute the user's eye have different reflectivity for infrared rays. Accordingly, the infrared rays generated from the infrared light emitting diode of the display panel 100 and irradiated to the eye have a difference in an amount of reflection depending on regions of the eye.

Accordingly, the infrared photodiodes IRPD arranged in the display panel 100 sense the infrared rays having different amounts of reflection depending on the regions of the eye to obtain an eye image, and by analyzing this, gaze information including eye position, eye blinking, etc. can be obtained.

As described above, according to the present embodiment, the infrared light emitting diode and the infrared photodiode, which are the gaze tracking modules that implement the user gaze tracking, can be formed below the light emitting diodes displaying the image in the corresponding subpixels with the dielectric layer interposed therebetween. Here, the cathode electrode of each of the infrared light emitting diode and the infrared photodiode, the dielectric layer, and the anode electrode of the light emitting diode can be formed in a sandwich structure of metal layer/dielectric layer/metal layer, so that the selective transmission structure that reflects the visible light in the wavelength ranges of red, green, and blue and transmits the infrared ray can be implemented.

As such, by forming the selective transmission structure in the subpixel, the emission efficiency of visible light can be sufficiently secured, while the infrared ray for tracking the user's gaze can be generated and irradiated onto the user's eyes, and the reflected infrared IR can be received and sensed.

Therefore, the user's gaze tracking modules using the infrared ray can be effectively embedded within the display panel, and accordingly, miniaturization and weight reduction of the head mounted display apparatus using the display panel can be realized, and user's wearing comfort can be improved.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device, comprising:
a substrate including a first subpixel;
an infrared light emitting diode which is in the first subpixel on the substrate and in which a second anode electrode, an infrared emitting layer, and a second cathode electrode are stacked;
a dielectric layer on the infrared light emitting diode; and
a light emitting diode which is in the first subpixel and in which a first anode electrode, a light emitting layer, and a first cathode electrode are stacked on the dielectric layer,
wherein a structure configured with the second cathode electrode, the dielectric layer, and the first anode electrode reflects visible light and transmits infrared ray.

2. The display device of claim 1, wherein the substrate further includes a second subpixel,
wherein the display device further comprises an infrared photodiode which is in the second subpixel on the substrate and in which a third anode electrode, an infrared receiving layer, and a third cathode electrode are stacked, and
wherein the dielectric layer is further located on the infrared photodiode, and the light emitting diode is further located in the second subpixel.

3. The display device of claim 2, wherein a structure configured with the third cathode electrode, the dielectric layer, and the first anode electrode reflects visible light and transmits infrared ray.

4. The display device of claim 3, wherein each of a first thickness of the first anode electrode, a second thickness of the second cathode electrode and a third thickness of the third cathode electrode is in a range from 150 Å to 250 Å, and a fourth thickness of the dielectric layer is in a range from 9800 Å to 10000 Å.

5. The display device of claim 3, wherein the structure configured with the second cathode electrode, the dielectric layer, and the first anode electrode, and the structure configured with the third cathode electrode, the dielectric layer, and the first anode electrode reflect red light, green light, and blue light, and transmits the infrared ray with a wavelength in a range from 910 nm to 930 nm.

6. The display device of claim 3, wherein each of the first anode electrode, the second cathode electrode, and the third cathode electrode is formed of a metal.

7. The display device of claim 6, wherein each of the first anode electrode, the second cathode electrode, and the third cathode electrode includes Ag, Cu, or Al, and the dielectric layer includes Al2Ox, SiO2, or SiNx.

8. The display device of claim 2, further comprising a reflective electrode between the substrate and the second anode electrode and between the substrate and the third anode electrode.

9. The display device of claim 8, wherein the reflective electrode is configured to reflect the infrared ray.

10. The display device of claim 2, further comprising:
a first driving transistor and a second driving transistor in the first subpixel, the first driving transistor connected to the light emitting diode, the second driving transistor connected to the infrared light emitting diode; and
the first driving transistor and a switching transistor in the second subpixel, the first driving transistor connected to the light emitting diode, the switching transistor connected to the infrared photodiode.

11. The display device of claim 2, wherein the first and second subpixels are arranged along a row line and/or a column line.

12. The display device of claim 2, wherein each of the second cathode electrode and the third cathode electrode extends along a row line or a column line,
wherein a low potential voltage is applied to the second cathode electrode of the infrared light emitting diode, and
wherein a bias voltage is applied to the third cathode electrode of the infrared photodiode.

13. The display device of claim 1, further comprising a bank formed at a boundary of each of the first and second subpixels and including a first bank layer and a second bank layer,
wherein an edge of the first anode electrode extends over an upper surface of the first bank layer and is covered by the second bank layer.

14. The display device of claim 13, wherein a contact hole is formed in the first bank layer,
wherein the first anode electrode is connected to a connection electrode through the contact hole, and
wherein the connection electrode is connected to a drain electrode of a transistor.

15. The display device of claim 2, wherein the substrate further includes a third subpixel, in which the infrared light emitting diode and the infrared photodiode are not disposed.

16. The display device of claim 1, wherein the dielectric layer has a refractive index of 1.5 to 2.5.

17. The display device of claim 2, wherein the first subpixel and the second subpixel are uniformly arranged in the substrate.

18. A display device, comprising:
a substrate including a plurality of subpixels;
a light emitting diode in one of the plurality of subpixels and emitting visible light;
an infrared light emitting diode or an infrared photodiode positioned below the light emitting diode in the one of the plurality of subpixels, the infrared light emitting diode emitting infrared ray, the infrared photodiode receiving the infrared ray; and
a dielectric layer interposed between a first anode electrode of the light emitting diode and a second cathode electrode of the infrared light emitting diode or the infrared photodiode,
wherein each of the first anode electrode and the second cathode electrode is formed of a metal and has a thickness in a range from 150 Å to 250 Å, and
wherein the dielectric layer has a thickness in a range from 9800 Å to 10000 Å.

19. The display device of claim 18, wherein a structure configured with the second cathode electrode, the dielectric layer, and the first anode electrode reflects red light, green light, and blue light, and transmits the infrared ray with a wavelength in a range from 910 nm to 930 nm.

20. The display device of claim 18, wherein each of the first anode electrode and the second cathode electrode includes Ag, Cu, or Al, and the dielectric layer includes Al2Ox, SiO2, or SiNx.

21. The display device of claim 18, further comprising a reflective electrode between the substrate and the infrared light emitting diode or infrared photodiode.

22. A head mounted display apparatus, comprising:
the display device of claim 1; and
an apparatus frame on which the display device is mounted.

23. The head mounted display apparatus of claim 22, wherein the infrared ray generated from the infrared light emitting diode and irradiated to user's eye have a difference in an amount of reflection depending on regions of the eye.
